(19) United States
(12) Patent Application Publication
(10) Pub. No.: US 2010/0252302 A1
(43) Pub. Date: Oct. 7, 2010

(54) CIRCUIT BOARD FOR MULTI-TYPE HEAT DISSIPATING DEVICES

(75) Inventors: Kuo Wei Tsao, Taipei (TW); Jian Tzuo Chen, Taipei (TW); Yueh Chih Chen, Taipei City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: ASUSTEK COMPUTER INC., Taipei (TW)

(21) Appl. No.: 12/752,756

(22) Filed: Apr. 1, 2010

(30) Foreign Application Priority Data
Apr. 2, 2009 (TW) 098111029

(51) Int. Cl. H05K 1/00

(52) U.S. Cl. 174/250

(57) ABSTRACT

The invention discloses a circuit board. The circuit board includes a body having an electric component holding portion according to the invention. A plurality of groups of fixing holes for fixing various types of heat dissipating devices are formed on the body adjacent to the electric component holding portion. With such a systematized layout, as a result, the number of fixing holes arranged is increased to improve the compatibility of circuit board for various heat dissipating devices, in spite of a limited space allowed on the circuit board.

### BACKGROUND OF THE INVENTION

1. Field of the Invention

The invention relates to a circuit board and, more particularly, to a computer circuit board having high compatibility with heat dissipating devices.

2. Description of the Related Art

High-efficiency central processing units (CPU) become more and more important in different kinds of information products. However, the CPU generates more heat along with its efficiency enhancing. As a result, manufacturers of heat dissipating devices such as cooling modules on the market develop high-efficiency radiator corresponding to the CPU to solve this problem.

Generally speaking, a circuit board may support different kinds of CPU that with different pins, and corresponding types of cooling modules applied to the CPUs may share fixing holes within a specific layout. However, with rapid development of semiconductor industry and various component structure provided, models of CPUs are quickly changed, and therefore, changes of layout of fixing holes formed on the circuit board are accordingly request due to an incompatibility between a cooling module for new model CPUs and old fixing hole layout, or a cooling module for old model CPUs and new fixing hole layout.

However, prompt and swift changes of fixing hole layout on circuit board are practically difficult to be realized. Uses inevitably have to purchase corresponding cooling module or circuit board that may fit with the other. This causes an additional expense.

### BRIEF SUMMARY OF THE INVENTION

In view of the problem as stated above, the invention provides a circuit board for multi-type heat dissipating devices.

According to an embodiment of the invention, the circuit board includes a body. The body has an electric component holding portion defined thereon, and multiple groups of fixing holes are formed on the body adjacent to the electric component holding portion. Two cross original axes are defined through the electric component holding portion, and at least two groups of heat dissipating device fixing holes are formed on the original axes with separating in an interval.

According to another embodiment of the invention, two cross deflection axes are further defined through the electric component holding portion, the deflection axes are coaxial and deflected relative to the original axes by an angle. In addition to fixing holes on the original axes, at least one group of fixing holes is further formed on the cross deflection axes.

With such a systematized layout, as a result, the number of fixing holes arranged is increased to improve the compatibility of circuit board for various heat dissipating devices, in spite of a limited space allowed on the circuit board.

These and other features, aspects and advantages of the present invention will become better understood with regard to the following description, appended claims, and accompanying drawings.

### BRIEF DESCRIPTION OF THE DRAWINGS

FIG. 1A to FIG. 1C are schematic diagrams showing the distances between fixing holes that fit respectively for cooling modules accommodating with three types of CPUs;

FIG. 2A and FIG. 2B are top views showing a circuit board according to a first embodiment of the invention;

FIG. 3 is a top view showing a circuit board according to a second embodiment of the invention; and

FIG. 4 is a top view showing a circuit board according to a third embodiment of the invention.

### DETAILED DESCRIPTION OF THE EMBODIMENTS

The invention provides a circuit board for multi-type heat dissipating devices, which provides a specific layout of fixing holes that allows a high compatibility with heat dissipating devices for CPUs of various models. The arrangement of present invention is totally based on modifying common circuit board itself, thus additional components, such as conventional cooling module securing brackets, is not needed.

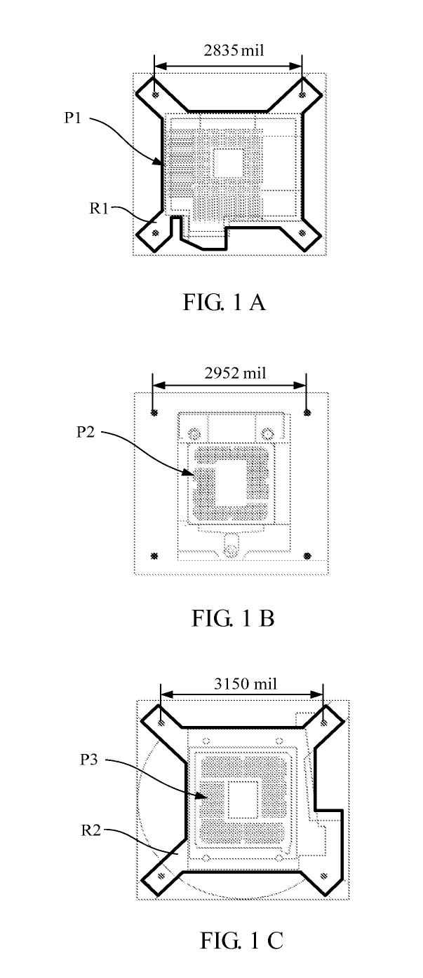

Heat dissipating devices, such as cooling modules are taken as examples to illustrate the invention in detail hereinafter. FIG. 1A to FIG. 1C are schematic diagrams showing the distances between fixing holes that fit respectively for cooling modules accommodating with three types of CPUs. P1 to P3 denotes three types of fixing holes layout for three types of CPUs as examples.

As shown in FIG. 1A, for the cooling module cooperating with a first type of CPU, the distance between adjacent fixing holes on the circuit board is 2835 mil (1000 mil is equal to one inch). As shown in FIG. 1B, for the cooling module cooperating with a second type of CPU, the distance between the adjacent fixing holes on the circuit board is 2952 mil. As shown in FIG. 1C, for the cooling module cooperating with a third type of CPU, the distance between the adjacent fixing holes on the circuit board is 3150 mil.

Additionally, a height limiting zone is usually defined on the circuit board for preventing the cooling module from interfering with other electronic components. For example, the area surrounded by a boldface line in FIG. 1A is a height limiting zone R1 defined on the electric component holding portion 12 according to the cooling module cooperating with the first type of CPU. The zone surrounded by the boldface line in FIG. 1C is a height limiting zone R2 defined on the electric component holding portion 12 according to the cooling module cooperating with the third type of CPU.

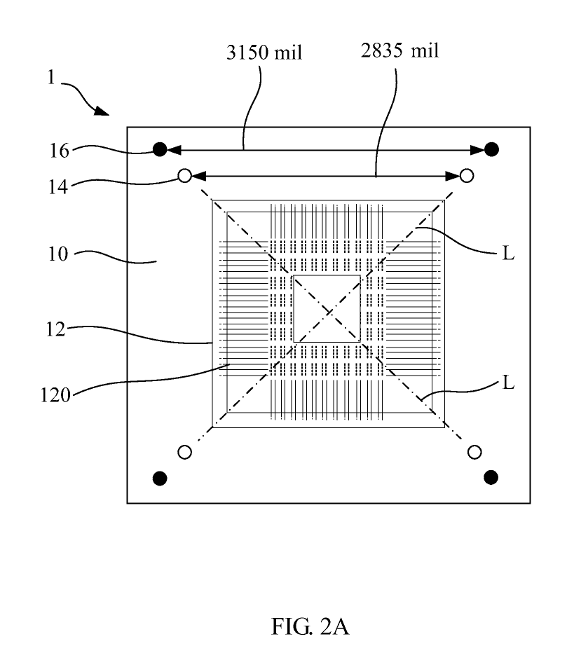

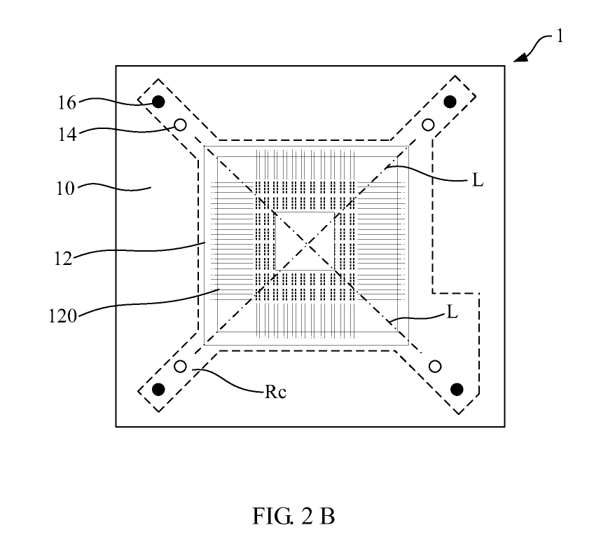

FIG. 2A is a top view showing a circuit board 1 according to a first embodiment of the invention. As shown in FIG. 2 A, a body 10 of the circuit board 1 has an electric component holding portion 12 thereon. In this embodiment, the heating element may be a CPU, the electric component holding portion 12 may be a CPU socket cooperating with the CPU, and a component number 120 may be pins. As shown in FIG. 2, the electric component holding portion 12 supports the first type of CPU and the third type of CPU.

As shown in FIG. 2A, a first group of fixing holes 14 for fixing the first cooling module and a second group of fixing holes 16 for fixing a second cooling module are formed at a peripheral region of the electric component holding portion 12 of the body 10. The first cooling module cooperates with the first type of CPU, and the second cooling module cooperates with the third type of CPU.

The first group of fixing holes 14 for fixing the first cooling module is formed on the body 10 to fix the first cooling module on the body 10. The distance between the adjacent fixing holes of the first group of fixing holes 14 may be 2835 mil as the conventionally preset value. Similarly, the second group of fixing holes 16 for fixing the second cooling module is formed on the body 10 to fix the second cooling module on the body 10. The distance between the adjacent fixing holes of the second group of fixing holes 16 may be 3150 mil as the conventionally preset value.

In terms of distribution, the first group of fixing holes 14 is formed on two cross original axes L passing through a center of the electric component holding portion 12, and the second group of fixing holes 16 is also formed on the original axes L. However, distances between a center of the electric component holding portion 12 and each fixing hole of different groups are different. Illustration please see FIG. 2A, for example, the second group of fixing holes 16 is farther from the center of the electric component holding portion 12 than the first group of fixing holes 14. As a result, no matter to hold the first type or the third type cooling module, corresponding group of fixing holes is implemented for securing the cooling module.

Additionally, as shown in FIG. 2B, the first group of fixing holes 14 and the second group of fixing holes 16 may be formed at a shared height limiting zone Rc defined on the electric component holding portion 12 for preventing the first cooling module or the second cooling module from interfering with other electronic component on the circuit board when it is installed on the circuit board, and the shared height limiting zone Rc is, for example, the zone surrounded by a dotted line. Note that the shared height limiting zone Rc is a union zone of the height limiting zone R1 for the first cooling module and the height limiting zone R2 for the second cooling module. For example, as shown in FIG. 2B, the shared height limiting zone Rc is the area surrounded by the boldface line in FIG. 1C, which is a combination of the height limiting zone R2 defined according to the cooling module and the height limiting zone R1 defined according to the cooling module cooperating with the first type of CPU.

For further illustration, each of the shared height limiting zone Rc, the height limiting zone R1 and the height limiting zone R2 means a determined area that defined on the circuit board according to size or height of specific model or type of component, in which installation of other large component might obstructing should be avoid, so as to preventing the component from interfering with other electronic component on the circuit board when it is installed on the circuit board

In practical usage, threads may be formed in the first group of fixing holes 14, and the first cooling module may have a plurality of through holes corresponding to the fixing holes 14 respectively and allowing a plurality of fixing elements such as screws to pass through and be fixed in the first group of fixing holes 14, and thus the first cooling module is secured on the body 10. The first cooling module also may have a plurality of fastening members passing through the first group of fixing holes 14 and fasten to the body 10, which is more convenient to assembly. The second group of fixing holes 16 and the second cooling module may be designed as stated above.

The number of groups of fixing holes for the cooling module is not limited to two in the first embodiment. More groups of fixing holes may be formed on the original axes L to accommodate with more types of cooling modules.

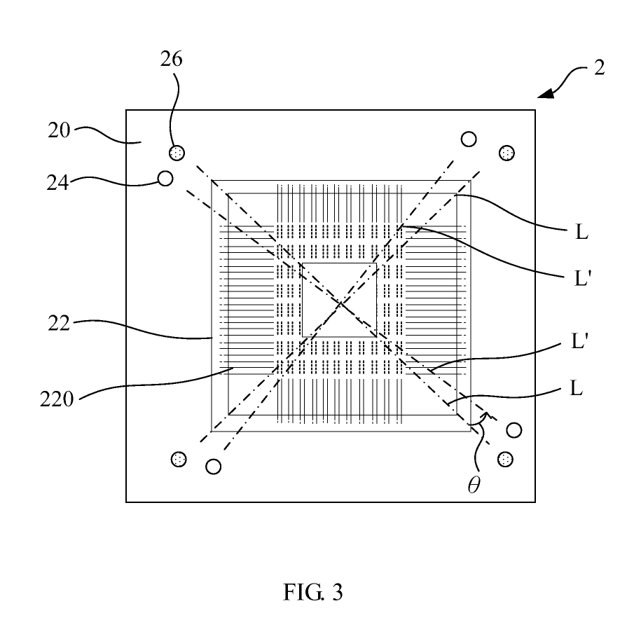

FIG. 3 is a top view showing a circuit board 2 according to a second embodiment of the invention. An electric component holding portion 22 may support the first type of CPU and the second type of CPU. As shown in FIG. 3, a first group of fixing holes 24 for fixing the first cooling module and a second group of fixing holes 26 for fixing the second cooling module are formed at the peripheral region of the electric component holding portion 22 of the body 20. The first cooling module cooperates with the first type of CPU, and the second cooling module cooperates with the second type of CPU.

The distance between the adjacent fixing holes of the first group of fixing holes 24 may be 2835 mil as the conventionally preset value. The distance between the adjacent fixing holes of the second group of fixing holes 26 may be 2952 mil as the conventionally preset value.

In the prior art, the holes in FIG. 1A for the first type of cooling module may overlap the holes in FIG. 1B for the second type of cooling module, this leads to a capacity limitation for fixing holes. To avoid such a capacity limitation, a second embodiment according to present invention provides that the second group of fixing holes 26 in FIG. 3 is formed on a pair of the cross original axes L passing through the center of the electric component holding portion 22, and the first group of fixing holes 24 is formed on two cross deflection axes L′. The cross deflection axes L′ is deflected relative to the original axes by an angle θ. As a result, the first cooling module and the second cooling module can cooperate with the first group of fixing holes 24 and the second group of fixing holes 26 to be fixed at the circuit board, respectively. Furthermore, the first group of fixing holes 24 and the second group of fixing holes 26 may be formed in the shared height limiting zone.

The number of the fixing holes is not limited and the cross deflection axes may be multiply defined by deflecting in different angles, such as to be compatible with more types of cooling modules installed.

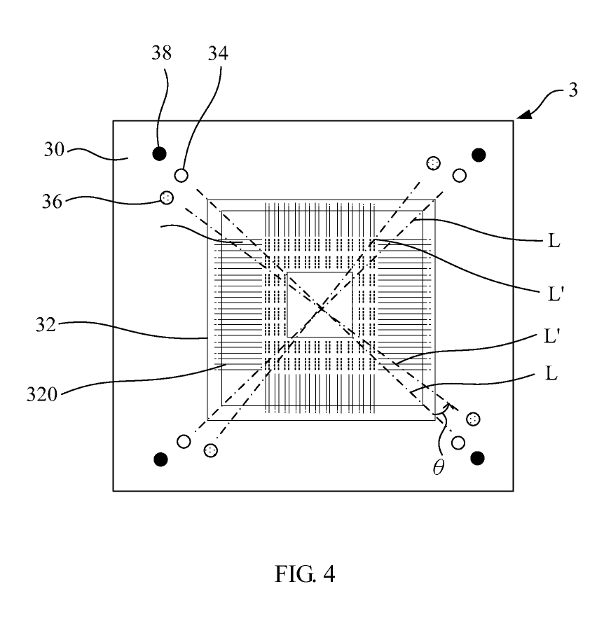

FIG. 4 is a top view showing a circuit board 3 according to a third embodiment of the invention. An electric component holding portion 32 in FIG. 3 can support the first type of CPU, the second type of CPU, and the third type of CPU. As shown in FIG. 4, the first group of fixing holes 34 for fixing the first cooling module, the second group of fixing holes 36 for fixing the second cooling module, and the third group of fixing holes 38 for fixing the third cooling module are formed at the peripheral region of the electric component holding portion 32 of the body 30. The first cooling module cooperates with the first type of CPU, the second cooling module cooperates with the second type of CPU, and the third cooling module cooperates with the third type of CPU.

The distance between the adjacent fixing holes of the first group of fixing holes 34 may be 2835 mil as the conventionally preset value. The distance between the adjacent fixing holes of the second group of fixing holes 36 may be 2952 mil as the conventionally preset value. The distance between the adjacent fixing holes of the third group of fixing holes 38 may be 3150 mil as the conventionally preset value.

In terms of distribution, the first group of fixing holes 34 is formed on the cross original axes L passing through the center of the electric component holding portion 32, and the third group of fixing holes 38 is also formed on the original axes L. As aforesaid, distances between the center of the electric component holding portion 12 and each fixing hole of different groups are different. Illustration please see FIG. 4, for example, the third group of fixing holes 38 is farther from the center of the electric component holding portion 12 than the first group of fixing holes 34. The second group of fixing holes 36 is formed on the cross deflection axes L′ deflected relative to the original axes L by the angle θ. The first group of fixing holes 34, the second group of fixing holes 36, and the third group of fixing holes 38 may be formed in a shared height limiting zone.

With such, not matter the electric component holding portion 32 holds the first type of CPU, the second type of CPU, or the third type of CPU, all the corresponding cooling modules may be fixed at the circuit board 3 according to the third embodiment of the invention.

The circuit boards in three embodiments of the invention as stated above are illustrated according to three types of CPUs. However, the number of the groups of fixing holes for the cooling modules and the distribution thereof may be modified according to practical demands. For example, they may be designed according to different types of CPUs, and they are not limited to the illustration in the embodiments of the invention. In brief, the circuit board in accordance with present invention defines various groups of fixing holes in a limited planar space, which allows more different types cooling modules to be installed.

Notely, aforesaid cooling module is a sort of heat dissipating device, and is not necessarily limited to be fan or any specific component served for cooling.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A circuit board, comprising:
a body having an electric component holding portion;
two cross original axes defined through the electric component holding portion; and
at least two groups of fixing holes being formed on the original axes adjacent to the electric component holding portion.

2. The circuit board according to claim 1, wherein the distances between a center of the electric component holding portion and each fixing hole of different groups are different.

3. The circuit board according to claim 1, further comprising at least two cross deflection axes defined on the electric component holding portion, wherein the cross deflection axes are deflected relative to the original axes by an angle, and at least one group of the fixing holes is formed on the cross deflection axes.

4. The circuit board according to claim 1, a shared height limiting zone is further defined on the electric component holding portion, and the at least two groups of fixing holes are located in the shared height limiting zone.

5. The circuit board according to claim 3, a shared height limiting zone is further defined on the electric component holding portion, and the at least two groups of fixing holes are located in the shared height limiting zone.
